(19) United States
(12) Patent Application Publication
(10) Pub. No.: US 2013/0288402 A1
(43) Pub. Date: Oct. 31, 2013

(54) ORGANIC EL DEVICE MANUFACTURING METHOD AND APPARATUS

(71) Applicants: Shigenori Morita, Ibaraki-shi (JP); Ryohei Kakiuchi, Ibaraki-shi (JP); Junichi Nagase, Ibaraki-shi (JP); Nobukazu Negishi, Ibaraki-shi (JP); Takahiro Nakai, Ibaraki-shi (JP); Naoko Ichieda, Ibaraki-shi (JP); Masahiko Watanabe, Ibaraki-shi (JP)

(72) Inventors: Shigenori Morita, Ibaraki-shi (JP); Ryohei Kakiuchi, Ibaraki-shi (JP); Junichi Nagase, Ibaraki-shi (JP); Nobukazu Negishi, Ibaraki-shi (JP); Takahiro Nakai, Ibaraki-shi (JP); Naoko Ichieda, Ibaraki-shi (JP); Masahiko Watanabe, Ibaraki-shi (JP)

(73) Assignee: NITTO DENKO CORPORATION, Ibaraki-shi, Osaka (JP)

(21) Appl. No.: 13/995,539

(22) PCT Filed: Nov. 4, 2011
(86) PCT No.: PCT/JP2011/075494

§ 371 Date: Jul. 12, 2013

(30) Foreign Application Priority Data
Dec. 28, 2010 (JP) 2010-292957

(51) Int. Cl. H01L 51/56

(52) U.S. Cl. CPC H01L 51/56
USPC 438/14; 118/712

(57) ABSTRACT

An organic EL device manufacturing method includes a vapor deposition step of supplying a substrate, and while moving the substrate with a side thereof, on which an electrode layer is not provided, in contact with a surface of a can roller that rotates, discharging an evaporated organic layer forming material from a nozzle of a vapor deposition source to form an organic layer over a side of the substrate on which the electrode layer is provided, wherein the vapor deposition step is performed while, using a distance measuring section capable of measuring a first distance to the substrate supported by the can roller, and a position adjusting section capable of adjusting a second distance between the nozzle of the vapor deposition source and a surface of the substrate, control is performed by the position adjusting section so that the second distance is constant.

### TECHNICAL FIELD

The present invention relates to a method and apparatus for manufacturing an organic EL device including an organic layer on an electrode layer formed over a substrate and emitting light from the organic layer.

### BACKGROUND ART

In recent years, organic EL (electroluminescence) devices are drawing attention as devices for use in next-generation low-power-consumption light-emitting display apparatuses. Basically, organic EL devices each include at least one organic layer including a light-emitting layer made of an organic light-emitting material and a pair of electrodes. Such organic EL devices emit light in various colors depending on the organic light-emitting materials. Furthermore, because of being self-light-emitting devices, the organic EL devices are drawing attention for use in displays such as those of televisions (TV).

An organic EL device includes at least one organic layer including a light-emitting layer, sandwiched between two electrode layers having polarities opposite to each other (sandwich structure), and the at least one organic layer includes an organic film having a thickness of several nanometers to several tens of nanometers. Furthermore, the organic layer sandwiched between the electrode layers is supported on a substrate, that is, the anode layer (electrode layer), the organic layer and the cathode layer are deposited on the substrate in this order to form an organic EL device. In the case of a plurality of organic layers included in an organic EL device, an anode layer is formed over a substrate, organic layers are sequentially deposited on the anode layer, and then a cathode layer is formed over the deposited organic layers, thereby forming an organic EL device.

As methods for forming organic layers over an anode layer formed over a substrate in manufacturing such organic EL device, vacuum vapor deposition and film coating are generally known. Among these methods, vacuum vapor deposition is mainly used because the purity of materials for forming the organic layers (organic layer forming materials) can be increased, facilitating provision of long-life products.

In vacuum vapor deposition as mentioned above, an organic layer is formed by performing vapor deposition using a vapor deposition source provided at a position facing a substrate in a vacuum chamber of a vapor deposition apparatus, and a vapor deposition source is provided for each organic layer. More specifically, each organic layer forming material is heated and evaporated in a heating section located in a vapor deposition source, and the evaporated organic layer forming material (evaporated material) is radially discharged from a nozzle provided at the vapor deposition source to deposit onto an anode layer formed over the substrate. The organic layer forming material is thereby vapor-deposited on the anode layer.

In such vacuum vapor deposition, what is called a batch process or a roll process is employed. A batch process is a process in which an organic layer is vapor-deposited on an anode layer for each of substrates each including an anode layer formed thereover. Meanwhile, a roll process is a process in which a strip-shaped substrate including an anode layer formed thereover, which has been rolled up, is continuously unwound (what is called a roll-to-roll manner), the unwound substrate is supported by a surface of a can roller, which rotates, to move the substrate along with the rotation to sequentially vapor-deposit respective organic layers on the anode layer, and the substrate with the respective organic layers vapor-deposited thereon is rolled up again. From among these processes, it is desirable that organic EL devices be manufactured using the roll process from the perspective of cost reduction.

However, where the roll process is employed in vacuum vapor deposition as mentioned above, an emission color varies from a desired emission color, which may result in a low-quality organic EL device being manufactured.

In particular, for vacuum vapor deposition, from the perspective of an increase in service life, a technique for reducing a distance between a vapor deposition source and a substrate in order to reduce an amount of moisture taken in a light-emitting layer has been proposed (cf., Patent Document 1); however, with such technique, it is more likely that low-quality organic EL devices with their emission colors varied from their respective desired emission colors such as mentioned above are manufactured.

### CITATION LIST

### Patent Document

Patent Document 1; Japanese Patent Application Laid-Open No. 2008-287996

### SUMMARY OF THE INVENTION

### Technical Problem

In view of the aforementioned problems, an object of the present invention is to provide an organic EL device manufacturing method and apparatus capable of manufacturing high-quality organic EL devices with suppression of emission color variation.

### Solution to Problem

As a result of the present inventors' diligent study in order to solve the aforementioned problem, it has been found that a variation of an emission color of a resulting organic EL device occurs due to a variation in thickness of an organic layer formed over a substrate and the variation in thickness occurs due to a variation in a distance between an edge of an opening of a nozzle of a vapor deposition source and a surface of the substrate (vapor deposition source-substrate distance or second distance) during vapor deposition.

Furthermore, as mentioned above, normally, a thickness of each organic layer in an organic EL device is around several nanometers to several tens of nanometers, and thus, a slight variation in thickness may largely affect the emission color. The vapor deposition source-substrate distance results from a variation in a position of the surface of the substrate supported by a can roller relative to the vapor deposition source due to, e.g., an eccentricity, expansion and/or a surface condition of the can roller, and such variation in the vapor deposition source-substrate distance may range up to around several tens of micrometers. It has been found that compared to a degree of variation in a vapor deposition source-substrate distance, a degree of variation in thickness of an organic layer, which is caused by the variation, is much larger: for example, where the vapor deposition source-substrate distance is 2 mm, if the distance varies by 20 μm (1%), a thickness of an organic layer varies by 2%.

In view of the above findings, it has been found that during vapor deposition, even if a variation in position of a surface of a substrate occurs, the variation in position is measured at a position upstream of a position where the vapor deposition step is performed, and based on a result of the measurement, a position of a vapor deposition source is adjusted so that the vapor deposition source-substrate distance is constant, whereby the vapor deposition source-substrate distance can be maintained constant, and consequently, a variation in thickness of an organic layer is suppressed, enabling manufacture of an organic EL device with suppression of emission color variation, and the present invention has been thereby completed.

In other words, an organic EL device manufacturing method according to the present invention provides

an organic EL device manufacturing method in which while a strip-shaped substrate with an electrode layer formed thereover is moved, an organic layer is formed over a side of the substrate on which the electrode layer is provided, the method including

a vapor deposition step of supplying the substrate, and while moving the substrate with a side thereof, on which the electrode layer is not provided, in contact with a surface of a can roller that rotates, discharging an evaporated organic layer forming material from a nozzle of a vapor deposition source arranged so as to face the can roller, to form an organic layer over the side of the substrate on which the electrode layer is provided,

wherein the vapor deposition step is performed while,

using a distance measuring section capable of measuring a first distance to the substrate supported by the can roller, at a position upstream of the nozzle in a direction of the movement of the substrate, and

a position adjusting section capable of adjusting a second distance between the nozzle of the vapor deposition source and a surface of the substrate,

based on a result of measurement of the first distance by the distance measuring section, control is performed by the position adjusting section so that the second distance is constant.

Here, the measurement of the first distance to the substrate by the distance measuring section includes measuring a distance from the distance measuring section to the substrate by measuring a distance from the distance measuring section to the electrode layer, in addition to measuring a distance from the distance measuring section to the substrate. Consequently, even if a position of the surface of the substrate that moves in such a manner that the substrate is supported by the can roller varies, the first distance is measured at the position upstream of the nozzle, and based on a result of the measurement, a position of the vapor deposition source is changed, whereby an adjustment can be made so that the second distance is constant. Accordingly, while the vapor deposition source-substrate distance is maintained constant irrespective of a variation in position of the surface of the substrate, an organic layer can be formed over the electrode layer formed over the substrate, by the vapor deposition source. Accordingly, a variation in thickness of the organic layer, which is caused by a variation in the vapor deposition source-substrate distance, can be suppressed, enabling provision of a high-quality organic EL device with suppression of emission color variation.

Also, in the present invention, it is preferable that the position adjusting section be capable of changing a position of the vapor deposition source by a change in shape of a piezoelectric actuator. Consequently, based on a result of measurement by the distance measuring section, the position of the vapor deposition source can be adjusted with better accuracy and without delay.

Also, in the present invention, it is preferable that the distance measuring section be provided at the vapor deposition source. Consequently, there is no need to separately provide a member for supporting the distance measuring section, enabling simplification of the apparatus configuration and reduction in number of members or parts.

Also, in the present invention, it is preferable that the distance between the nozzle and the surface of the substrate be not more than 15 mm.

Consequently, even where a thickness of an organic layer varies more easily, the vapor deposition step can be performed while the vapor deposition source-substrate distance is maintained constant, and thus, a higher effect can be provided.

Also, an organic EL device manufacturing apparatus according to the present invention includes:

a substrate supply section that supplies a strip-shaped substrate with an electrode layer formed thereover;

a can roller that rotates along with movement of the substrate while being in contact with a side of the supplied substrate on which the electrode layer is not provided;

a vapor deposition source arranged so as to face the can roller, the vapor deposition source discharging an evaporated organic layer forming material from a nozzle to form an organic layer over a side of the substrate on which the electrode layer is provided, the substrate being in contact with the can roller;

a distance measuring section capable of measuring a first distance to the substrate supported by the can roller, at a position upstream of the nozzle in a direction of the movement of the substrate; and

a position adjusting section capable of adjusting a second distance between the nozzle of the vapor deposition source and a surface of the substrate,

wherein the vapor deposition step can be performed while, based on a result of measurement of the first distance by the distance measuring section, a position of the vapor deposition source is adjusted by the position adjusting section so that the second distance is constant.

### Advantageous Effect of Invention

As described above, the present invention enables manufacturing of high-quality organic EL devices with suppression of emission color variation.

### BRIEF DESCRIPTION OF DRAWINGS

FIG. 1 is a schematic cross-sectional side view of an organic EL device manufacturing apparatus according to an embodiment of the present invention.

FIG. 2 is a schematic side view of a configuration of a part around a vapor deposition source and a can roller in a vacuum chamber.

FIG. 3 is a schematic side view illustrating a state in which a vapor deposition source has moved close to a substrate.

FIG. 4 is a schematic side view illustrating a state in which a vapor deposition source has moved away from a substrate.

FIG. 5A is a schematic cross-sectional side view of an example of a configuration of layers of an organic EL device.

FIG. 5B is a schematic cross-sectional side view of an example of a configuration of layers of an organic EL device.

FIG. 5C is a schematic cross-sectional side view of an example of a configuration of layers of an organic EL device.

### DESCRIPTION OF EMBODIMENT

An organic EL device manufacturing method and apparatus according to the present invention will be described below with reference to the drawings.

First, an organic EL device manufacturing apparatus and method according to a first embodiment of the present invention will be described.

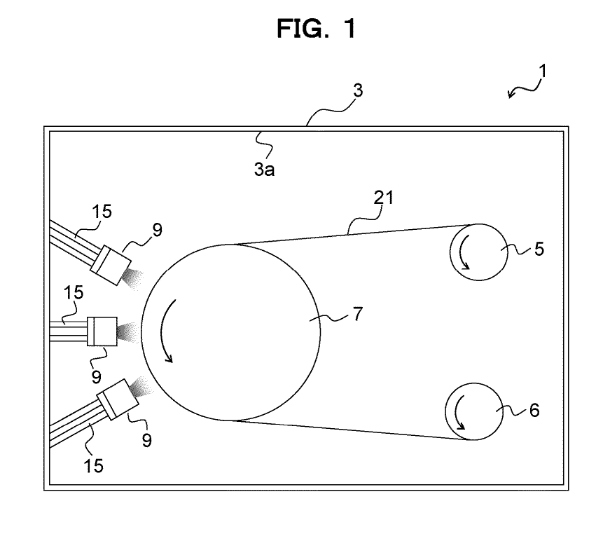

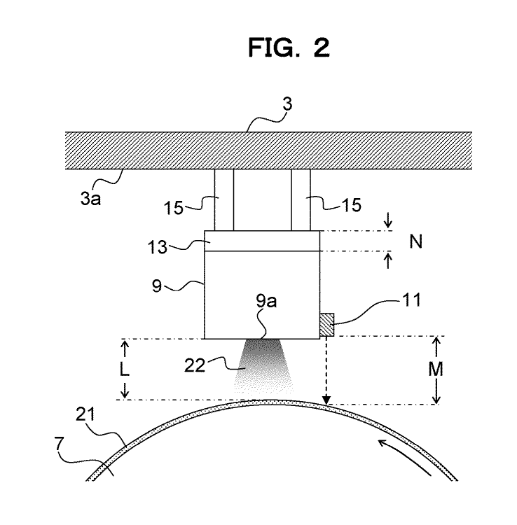

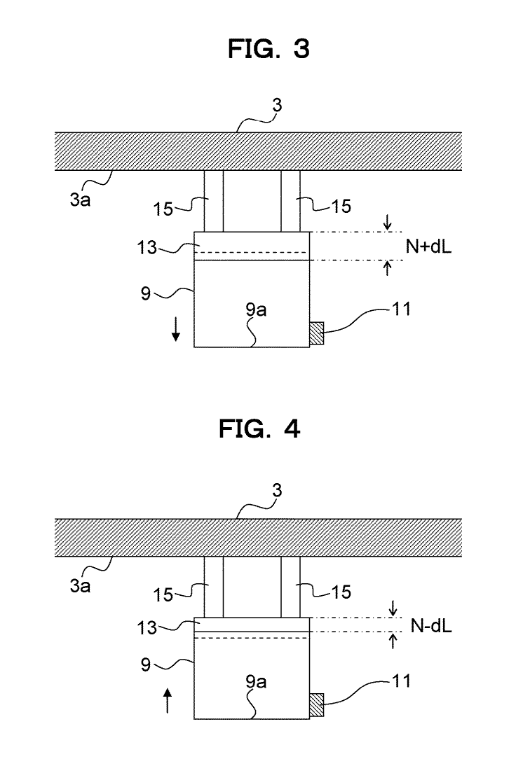

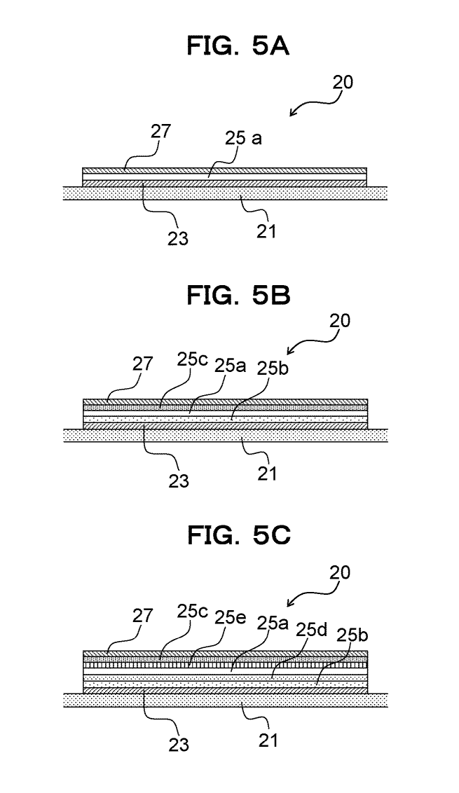

FIG. 1 is a schematic cross-sectional side view of an organic EL device manufacturing apparatus according to a first embodiment of the present invention, FIG. 2 is a schematic side view of a configuration of a part around a vapor deposition source and a can roller in a vacuum chamber, FIG. 3 is a schematic side view illustrating a state in which a vapor deposition source has moved close to a substrate, FIG. 4 is a schematic side view illustrating a state in which a vapor deposition source has moved away from a substrate, and FIGS. 5A, 5B and 5C are schematic cross-sectional side views each illustrating an example of a layer configuration for an organic EL device.

As illustrated in FIG. 1, an organic EL device manufacturing apparatus 1 is a vapor deposition apparatus including a vacuum chamber 3, and in the vacuum chamber 3, roughly, a substrate supply device 5, which is a substrate supply section, a can roller 7, vapor deposition sources 9 and a substrate collection device 6 are arranged. The inside of the vacuum chamber 3 is made to enter a pressure-reduced state by a non-illustrated vacuum generator so that a vacuum area can be formed inside.

As the substrate supply device 5, a supply roller 5 that pays a rolled-up strip-shaped substrate 21 out is provided. As the substrate collection device 6, a wind-up roller 6 that winds the fed-out substrate 21 up is provided. In other words, what is called a roll-to-roll method in which the substrate 21 fed out from the supply roller 5 is supplied to the can roller 7 and then wound up by the wind-up roller 6 is employed.

The can roller 7 is made of a stainless steel and is configured to rotate. The can roller 7 is arranged at a position allowing the substrate 21, which is fed out (supplied) from the supply roller 5 and wound up by the wind-up roller 6, to be wound over the can roller 7 at a predetermined tension, and a circumferential face (surface) of the can roller 7 supports a side of the substrate 21 on which an electrode layer is not provided (more specifically, a side opposite to a side on which an anode layer is provided). Also, as a result of the can roller 7 rotating (rotating counterclockwise in FIG. 1), the wound (supported) substrate 21 can be moved in a direction of the rotation together with the can roller 7.

The can roller 7 preferably includes a temperature control mechanism such as a cooling mechanism inside, enabling a temperature of the substrate 21 to be stabilized during formation of an organic layer over the substrate 21, which will be described later. An outer diameter of the can roller 7 may be determined in a range of, for example, 300 to 2000 mm.

Upon rotation of the can roller 7, the substrate 21 is consecutively fed out from the supply roller 5 along with the rotation, and the fed-out substrate 21 moves in the direction of the rotation while being in contact with and thereby supported by the circumferential face of the can roller 7, and the substrate 21 separated from the can roller 7 is wound up by the wind-up roller 6.

For a material for forming the substrate 21, a flexible material that is not damaged when looped over the can roller 7 is used, and examples of such material can include metal materials, non-metal inorganic materials and resin materials.

Examples of the metal materials include stainless steels, alloys such as iron-nickel alloys, copper, nickel, iron, aluminum and titanium. Furthermore, examples of the aforementioned iron-nickel alloys can include alloy 36 and alloy 42. From among these materials, it is preferable that the metal material be a stainless steel, copper, aluminum or titanium, from the perspective of ease of application of the metal material to the roll process. Furthermore, the substrate made of such metal material preferably has a thickness of 5 to 200 μm from the perspective of ease of handling and winding up the substrate.

Examples of the non-metal inorganic materials can include glass. In this case, as the substrate made of a non-metal inorganic material, a flexible thin-film glass can be used. Furthermore, the substrate made of such non-metal inorganic material preferably has a thickness of 5 to 500 μm from the perspective of sufficient mechanical strength and moderate plasticity.

Examples of the resin materials can include synthetic resins such as thermosetting resins and thermoplastic resins. Examples of such synthetic resins can include polyimide resins, polyester resins, epoxy resins, polyurethane reins, polystyrene resins, polyethylene resins, polyamide resins, acrylonitrile butadiene styrene (ABS) copolymer resins, polycarbonate resins, silicone resins and fluorine resins. Furthermore, for the substrate made of such resin material, a film of any of the aforementioned synthetic reins can be used, for example. Furthermore, the substrate made of such resin material preferably has a thickness of 5 to 500 μm from the perspective of sufficient mechanical strength and moderate plasticity.

For the substrate 21, specifically, one with an anode layer 23 (see FIGS. 5A to 5C) formed in advance by sputtering can be used.

For a material for forming the anode layer 23, any of various transparent conductive materials such as indium zinc oxide (IZO) and indium tin oxide (ITO), metals such as gold, silver and platinum, and alloy materials can be used.

The vapor deposition source 9 is provided for each of the organic layers in at least one organic layer including a light-emitting layer 25a (cf. FIGS. 5A to 5C). Each vapor deposition source 9 is arranged at a position facing a region of the circumferential surface of the can roller 7 that supports the substrate 21, and vapor-deposits a material for forming an organic layer (organic layer forming material 22) over the substrate 21, thereby sequentially forming organic layers over the anode layer 23 formed over the substrate 21 (cf. FIGS. 5A to 5C). A configuration of such vapor deposition sources 9 is not limited as long as the configuration includes a nozzle capable of discharging an organic layer forming material 22 evaporated by heat etc., toward the substrate 21.

Each vapor deposition source 9, which can accommodate an organic layer forming material 22, and includes a nozzle 9a and a heating section (not illustrated). The nozzle 9a is arranged so as to face the region of the can roller 7 that supports the substrate 21. The heating section is configured to heat and evaporate the organic layer forming material 22, and the evaporated organic layer forming material 22 is discharged to the outside from the nozzle 9a.

Then, upon the organic layer forming material 22 being heated in the vapor deposition source 9, the organic layer forming material 22 is evaporated, the evaporated organic layer forming material 22 is discharged from the nozzle 9a toward the substrate 21, and deposited on the substrate 21. As a result of the evaporated organic layer forming material 22 being deposited on the substrate 21, an organic layer is formed over the anode layer 23 formed over the substrate 21.

The organic layers are not specifically limited as long as the organic layers include at least the light-emitting layer 25a, and for example, as illustrated in FIG. 5A, one organic layer, i.e., only the light-emitting layer 25a, can be formed over the anode layer 23. For example, as illustrated in FIG. 5B, a hole injection layer (organic layer) 25b, a light-emitting layer 25a and an electron injection layer (organic layer) 25c can be deposited in this order to provide a structure of three deposited organic layers, as necessary. Alternatively, as necessary, a hole transport layer (organic layer) 25d (cf. FIG. 5C) can be interposed between the light-emitting layer 25a and the hole injection layer 25b illustrated in FIG. 5B or an electron transport layer (organic layer) 25e (see FIG. 5C) can be interposed between the light-emitting layer 25a and the electron injection layer 25c to provide a structure of four deposited organic layers.

Furthermore, as illustrated in FIG. 5C, a hole transport layer 25d can be interposed between the hole injection layer 25b and the light-emitting layer 25a, and an electron transport layer 25e can be interposed between the light-emitting layer 25a and the electron injection layer 25c to provide a structure of five deposited organic layers. Although each organic layer is ordinarily designed to have a thickness of around several nanometers to several tens of nanometers, such thickness is not specifically limited because the thickness is arbitrarily determined depending on, e.g., the organic layer forming material 22 and/or the light emitting property.

For a material for forming the light-emitting layer 25a, for example, tris(8-hydroxyquinoline)aluminum (Alq3), and 4,4′-N,N′-dicarbazolyl biphenyl (CBP) with iridium complex (Ir(ppy)₃) doped therein, can be used.

For a material for forming the hole injection layer 25b, for example, copper phthalocyanine (CuPc) or 4,4′-bis[N-4-(N,N-di-m-tolylamino)phenyl]-N-phenylamino]biphenyl (DNTPD) can be used.

For a material for forming the hole transport layer 25c, for example, 4,4′-bis[N-(1-naphthyl)-N-phenylamino]biphenyl (α-NPD) or N,N′-diphenyl-N,N′-bis(3-methylphenyl)-1,1′-biphenyl 4,4′-diamine (TPD) can be used.

For a material for forming the electron injection layer 25c1, for example, lithium fluoride (LiF), cesium fluoride (CsF) or lithium oxide (Li₂O) can be used.

For a material for forming the electron transport layer 25e, for example, tris(8-hydroxyquinoline)aluminum (Alq3), bis(2-methyl-8-quinolinolato)-4-phenylphenolate-aluminum (BAlq) or OXD-7(1,3-bis[5-(p-tert-butylphenyl)-1,3,4-oxadiazole-2-yl])benzene can be used.

One and more of vapor deposition sources 9 can be arranged according to the configuration and/or number of organic layers formed over the anode layer 23 of the substrate 21 as described above. For example, as illustrated in FIG. 5B, where three organic layers are deposited, three vapor deposition sources 9 can be arranged for the respective organic layers as shown in FIG. 1. Where a plurality of vapor deposition sources 9 are provided as described above, a first organic layer is vapor-deposited on the anode layer 23 by a vapor deposition source 9 arranged at a most upstream position in a direction of rotation of the can roller 7 (the moving direction of the substrate 21) and then, a second organic layer is sequentially vapor-deposited on the first organic layer by means of a vapor deposition source 9 on the downstream side.

Here, when a variation in thickness of each organic layer formed over the substrate 21 is large, a problem of a change of an emission color in an organic EL device occurs. The variation in thickness of each respective organic layer occurs due to a variation in a distance between a nozzle 9a of the relevant vapor deposition source 9 (more specifically, an edge of an opening of the nozzle 9a) and a surface of the substrate 21 (vapor deposition source-substrate distance L), and the vapor deposition source-substrate distance L occurs due to a variation in a position of the surface of the substrate (surface position) relative to the vapor deposition source 9, and hence a variation in the distance between the nozzle 9a of the vapor deposition source 9 and the surface of the can roller 7.

Furthermore, the variation in the surface position occurs according to, e.g., an assembling accuracy or a processing accuracy for the can roller 7, an eccentricity of the can roller 7, expansion of a material constituting the can roller 7 due to heat during vapor deposition and/or irregularity of the surface of the can roller 7, and it is highly possible that such variation ranges up to around several tens of micrometers.

Normally, a thickness of each organic layer in each organic EL device is around several nanometers to several tens of nanometers, and thus, the variation in the surface position largely affects a variation in thickness of each organic layer. For example, where the vapor deposition source-substrate distance L is set to 2 mm, when the distance varies by 20 μm (1%), the thickness of each organic layer varies by 2%, that is, the thickness of each organic layer can vary at a ratio of variation around twice the ratio of variation in the aforesaid distance.

As described above, a slight change in thickness of an organic layer largely affects the emission color, and a slight change in the distance L largely affects the thickness. Therefore, even if there is a variation in the surface position of the substrate 21, the position of each vapor deposition source 9 is adjusted according to the variation, whereby the vapor deposition source-substrate distance L is maintained constant and a variation in thickness of each organic layer formed over the anode layer 23 on the substrate 21 is suppressed. Here, the vapor deposition source-substrate distance L refers to a distance between the nozzle 9a and the surface of the substrate 21 on a virtual line connecting the can roller 7 and the nozzle 9a at a shortest distance.

In the present embodiment, as illustrated in FIG. 2, at an end portion of each vapor deposition source 9 on the upstream side in a direction of rotation of the can roller 7 (right side in the Figure), a distance measuring member (distance measuring section) 11 is provided.

Also, at an end portion of each vapor deposition source 9 on the side opposite to the can roller 7 (upper side in the Figure), a position adjusting member (position adjusting section) 13 is provided, and an end portion of the position adjusting member 13 on the side opposite to the vapor deposition source 9 (upper side in the Figure) is fixed to an inner wall 3a (fixing portion) of the vacuum chamber 3 via a fixing member 15. In other words, the vapor deposition source 9 is fixed to the inner wall 3a of the vacuum chamber 3 via the position adjusting member 13.

Also, the distance measuring member 11 and the position adjusting member 13 are electrically connected to, for example, a control section (not illustrated) such as a central processing unit (CPU).

The distance measuring member 11 is provided to measure a distance M from the distance measuring member 11 to the substrate 21 in order to determine an amount of movement of the vapor deposition source 9 by the position adjusting member 13, which will be described later. For example, when the distance M has been measured by the distance measuring member 11, a result of the measurement is transmitted to the control section, and the control section calculates a distance variation dM from a reference distance Ms. The measurement of the distance M includes measuring the distance M from the distance measuring member 11 to the substrate 21, and obtaining the distance M by measuring a distance from the distance measuring member 11 to the anode layer 23.

Furthermore, examples of cases where the distance M is measured by the distance measuring member 11 include a method in which a distance variation dM is measured by the distance measuring member 11 and the distance variation dM is transmitted to the control section and the distance M is measured as a sum of the reference distance Ms and the distance variation dM. In this case, there is no need to calculate the distance variation dM in the control section.

Also, the distance measuring member 11 is preferably a contactless one capable of measuring the distance M without contact with the substrate 21. Consequently, it is possible to prevent an unwanted variation in the surface position of the substrate 21 from occurring as a result of the distance measuring member 11 coming into contact with the substrate 21.

Examples of the above-described distance measuring member 11 that is capable of measuring a distance variation dM and is a contactless one can include displacement sensors. A displacement sensor includes a light-projecting element that projects laser light and a light-receiving element that receives reflected light of the laser light projected from the light-projecting element onto an object, and detects a variation in height of the object as a variation in a position of reception of the reflected light in the light-receiving element (that is, a variation in a distance between the object and the light-receiving element). With such displacement sensor, an amount of variation from a predetermined reference distance Ms can be measured as a distance variation dM.

The distance measuring member 11 is arranged at a position upstream of the nozzle 9a, above the substrate 21 supported by the can roller 7 (in contact with the can roller 7). Consequently, the distance measuring member 11 can measure the distance M to the substrate 21 at a position upstream, in the direction of the rotation, of an area (vapor deposition area) facing the nozzle 9a of the vapor deposition source 9.

Such arrangement of the distance measuring member 11 is not limited as long as the distance measuring member 11 is arranged upstream of the nozzle 9a in the direction of rotation of the can roller 7 and can measure the distance M to the substrate 21. However, if the distance measuring member 11 is excessively close to the nozzle 9a, the distance measuring member 11 may be affected by the relevant evaporated organic layer forming material 22, resulting in a decrease in measurement accuracy, and if the distance measuring member 11 is excessively away from the nozzle 9a, an unwanted variation in the distance M may occur until an area of the substrate 21 measured by the distance measuring member 11 (measurement area) reaches the vapor deposition area, making it difficult to reflect a result of the measurement by the distance measuring member 11 in a distance variation dL in the vapor deposition source-substrate distance L, which will be descried later, with good accuracy.

Accordingly, the arrangement of the distance measuring member 11 can be set taking such point into account, and preferably, the distance measuring member 11 can be arranged so as to measure the distance M at a site that is 100% to 2000% of the distance L toward the upstream side of the substrate from an intersection between the virtual line and the surface of the substrate. Also, for example, the distance measuring member 11 can be arranged at an end portion of the vapor deposition source 9 on the upstream side of the can roller 7 while such point is taken into account. Consequently, there is no need to separately provide a member for supporting the distance measuring member 11, enabling simplification of the apparatus configuration and reduction in number of members.

The position adjusting member 13 is provided to change a position of the vapor deposition source 9 relative to the substrate 21. Also, the position adjusting member 13 changes the position of the vapor deposition source 9 based on an electric signal from the control section according to the above-described distance variation dM, and such change of the position makes the vapor deposition source 9 move in a direction close to/away from the substrate 21.

Then, along with the movement of the vapor deposition source 9, the nozzle 9a moves relative to the substrate 21, enabling adjustment of the vapor deposition source-substrate distance L. The position adjusting member 13 is not specifically limited as long as a shape of the position adjusting member 13 can be changed so that the vapor deposition source 9 moves close to/away from the substrate 21, and examples of the position adjusting member 13 include, e.g., electric actuators, hydraulic actuators and piezoelectric actuators.

From among them, it is preferable that the position adjusting member 13 is a piezoelectric actuator. A piezoelectric actuator includes a piezoelectric element such as ceramic, and upon a voltage being applied thereto, a thickness of the piezoelectric actuator varies according to the applied voltage. Such change in shape of the piezoelectric actuator enables a change of the position of the vapor deposition source 9. As described above, a piezoelectric actuator is used as the position adjusting member 13, enabling the position of the vapor deposition source 9 to be adjusted with better accuracy.

Here, the position adjusting member 13 is fixed to the inner wall 3a of the vacuum chamber 3 via a rod-like fixing member 15. Consequently, the vapor deposition source 9 is fixed to the inner wall 3a via the position adjusting member 13. The fixing member 15 preferably includes a metal such as a stainless steel, which does not cause, e.g., expansion by heat in the vacuum chamber 3, and consequently, an accuracy of measurement by the distance measuring member 11 and an accuracy of position adjustment by the position adjusting member 13 can be enhanced.

Next, position adjustments of the vapor deposition source 9 where the above-described displacement sensor is used as the distance measuring member 11 and a piezoelectric actuator having a thickness N is used as the position adjusting member 13 will be described.

The vapor deposition source-substrate distance L is set to a predetermined reference distance Ls in advance, and the aforementioned reference distance Ms for the distance measuring member 11 is set according to the predetermined reference distance Ls. Also, in the control section, a parameter for associating a distance variation dM measured by the distance measuring member 11 with a distance variation dL in the vapor deposition source-substrate distance L when the measurement area of the substrate 21 reaches the vapor deposition area is stored.

A distance variation dM measured by the distance measuring member 11 is transmitted to the control section, and upon receipt of the distance variation dM from the distance measuring member 11, the control section calculates a distance variation dL according to the distance variation dM based on the parameter. Then, at a timing when the measurement area of the substrate 21 reaches the vapor deposition area, the applied voltage is adjusted by an amount corresponding to the distance variation dL to change the thickness N of the piezoelectric actuator, thereby moving the vapor deposition source 9 by means of the position adjusting member 13. Consequently, the position of the vapor deposition source 9 is adjusted so that the distance variation dL is offset.

For example, if the surface of the substrate 21 moves away from the vapor deposition source 9 and a distance variation dM that is an increase amount is measured by the distance measuring member 11, the thickness N of the piezoelectric actuator is increased by an amount corresponding to a distance variation dL according to such increase amount (N+dL) as illustrated in FIG. 3. Consequently, the vapor deposition source-substrate distance L is adjusted to the distance Ls.

Meanwhile, for example, when the surface of the substrate 21 moves close to the vapor deposition source 9 and a distance variation dM that is a decrease amount is measured by the distance measuring member 11, the thickness N of the piezoelectric actuator is decreased by an amount corresponding to a distance variation dL according to such decrease amount (N−dL) as illustrated in FIG. 4. Consequently, vapor deposition source-substrate distance L is adjusted to the distance Ls. The aforementioned timing for increasing/decreasing the thickness of the piezoelectric actuator is set in advance and stored in the control section as data, and such timing is controlled by the control section.

As described above, based on a result of measurement by the distance measuring member 11, the position of the vapor deposition source 9 can be adjusted by the position adjusting member 13 so that the vapor deposition source-substrate distance L is constant at the reference distance Ls. Consequently, during vapor deposition of an organic layer, the vapor deposition source-substrate distance L can be maintained constant at the reference distance Ls, enabling suppression of a variation in thickness of the organic layer, which results from a variation in the vapor deposition source-substrate distance L. Accordingly, an emission color variation in the organic EL device 20 can be suppressed.

Furthermore, as the vapor deposition source-substrate distance L is smaller, a variation of the distance L is likely to largely affects a variation in thickness of an organic layer. Taking such point into account, the vapor deposition source-substrate distance L is preferably not more than 15 mm, more preferably not more than 5 mm. Where the distance L is not more than 15 mm, even if a thickness of an organic layer more easily varies, the vapor deposition step can be performed while the distance L between the nozzle 9a of the vapor deposition source 9 and the surface of the can roller 7 is maintained constant, and thus, a higher effect can be provided.

Organic layers are vapor-deposited on the anode layer 23 formed over the substrate 21 as described above and then a cathode layer 27 is formed over an uppermost surface of the organic layers by a non-illustrated vacuum film forming device such as a sputtering device, whereby an organic EL device 20 in which the anode layer 23, the organic layers and the cathode layer 27 are deposited in this order on the substrate 21 is formed (manufactured) as illustrated in FIGS. 5A to 5C. For the cathode layer 27, e.g., aluminum (Al), silver (Ag), ITO, an alkali metal or an alloy containing an alkali earth metal can be used.

It is also possible that, at the position in the vacuum chamber 3 that faces the region of the can roller 7 that supports the substrate 21, a vacuum film forming device for forming the anode layer 23 is arranged upstream of the vapor deposition sources 9, which are to form the organic layers, with respect to the direction of rotation of the can roller 7, and the vacuum film forming device for forming the cathode layer 27 is arranged downstream of the vapor deposition sources 9, whereby after formation of the anode layer 23 over the substrate 21, which moves while being supported by the can roller 7, the organic layers are vapor-deposited and the cathode layer 27 are further formed over the substrate 21.

Otherwise, where a material that can be vapor-deposited by a vapor deposition source is used for a material for each of the anode layer 23 and the cathode layer 27, the vapor deposition sources 9 for the anode layer 23 and the cathode layer 27 are arranged in the vacuum chamber 3, and the anode layer 23, the organic layers and the cathode layer 27 are successively vapor-deposited in this order on the substrate 21, enabling formation of the organic EL device 20.

Next, an organic EL device manufacturing method according to the first embodiment using the above-described manufacturing apparatus will be described.

An organic EL device manufacturing method according to the present invention provides an organic EL device manufacturing method in which while a strip-shaped substrate with an electrode layer formed thereover is moved, a layer including an organic EL film is formed by vapor deposition, the method including a vapor deposition step of supplying the substrate, and while moving the substrate with a side thereof, on which the electrode layer is not provided, in contact with a surface of a can roller that rotates, discharging an evaporated organic layer forming material from a nozzle of a vapor deposition source arranged so as to face the can roller, to form an organic layer over the side of the substrate on which the electrode layer is provided, wherein the vapor deposition step is performed while, using a distance measuring section capable of measuring a first distance to the substrate supported by the can roller, at a position upstream of the nozzle in a direction of the movement of the substrate, and a position adjusting section capable of adjusting a second distance between the nozzle of the vapor deposition source and a surface of the substrate, and based on a result of measurement of the first distance by the distance measuring section, control is performed by the position adjusting section so that the second distance is constant.

In the organic EL device manufacturing method according to the present embodiment, first, a substrate 21 over which an anode layer 23 has been formed on one surface thereof in advance by, e.g., sputtering, which has then been rolled up, is fed out from the substrate supply device 5 under a reduced-pressure atmosphere.

Next, while the fed-out substrate 21 is moved with a side opposite to a side over which the anode layer 23 has been formed in contact with the surface of the can roller 7, an organic layer forming material 22 containing a light-emitting layer 25a (see FIGS. 5A to 5C) is evaporated by the relevant vapor deposition source 9 arranged so as to face the can roller 7, and the evaporated organic layer forming material 22 is discharged from the nozzle 9a and vapor-deposited on the anode layer 23 on the substrate 21 supported by the can roller 7.

In this vapor deposition step, vapor deposition is performed while, using the distance measuring member 11 (distance measuring section) capable of measuring the distance M (first distance) between the distance measuring member 11 and the surface of the substrate 21 supported by the can roller 7 at a position upstream of the nozzle 9a in a direction of the movement of the substrate 21, and the position adjusting member 11 capable of adjusting the distance L (second distance) between the nozzle 9a and the surface of the substrate 21 by changing the position of the vapor deposition source 9 relative to the substrate 21, and based on a result of measurement of the distance M (first distance) by the distance measuring member 11, the position of the vapor deposition source 9 is adjusted by the position adjusting member 13 so that the distance L is constant at the reference distance Ls.

More specifically, a distance variation dM in the distance to the surface of the substrate 21 is measured by the distance measuring member 11 provided at the vapor deposition source 9 at the position upstream of the nozzle 9a of the vapor deposition source 9 in the direction of rotation of the can roller 7, at a position of measurement by the distance measuring member 11 (position where laser light is projected), and based on a result of the measurement, at a timing when the measurement area of the substrate 21 reaches the vapor deposition area, the position of the vapor deposition source 9 is adjusted by the position adjusting member 13 by an amount of a distance variation dL in the vapor deposition source-substrate distance L corresponding to the distance variation dM. Where an piezoelectric actuator is used as the position adjusting member 13 as described above, an applied voltage is adjusted to increase/decrease the thickness N of the piezoelectric actuator. Consequently, the vapor deposition source-substrate distance L can be made to be constant at the reference distance Ls.

Also, where a plurality of organic layers are formed over the anode layer 23, at respective timings when the measurement area of the substrate 21 reaches vapor deposition areas for respective vapor deposition sources 9, the positions of the respective vapor deposition sources 9 are adjusted in such a manner as described above.

As described above, the organic layer(s) are formed over the anode layer 23 formed over the substrate 21 while the vapor deposition source-substrate distance L is made to be constant and then the substrate 21 with the organic layer(s) vapor-deposited thereon is wound up by the wind-up roller 6. Furthermore, over the organic layer(s) formed over the wound-up substrate 21, the cathode layer 27 is formed by the non-illustrated sputtering device, whereby an organic EL device 20 in which the anode layer 23, the organic layer(s) and the cathode layer 27 are deposited in this order on the substrate 21 can be formed.

As described above, the manufacturing method according to the present embodiment includes a vapor deposition step of supplying the strip-shaped substrate 21 with the anode layer 23 (electrode layer) formed thereover, and while moving the substrate 21 with a side thereof, on which the anode layer 23 is not provided, in contact with the surface of the can roller 7 that rotates, discharging the evaporated organic layer forming material 22 from the nozzle 9a of a vapor deposition source 9 arranged so as to face the can roller 7 to form an organic layer over a side of the substrate 21 on which the anode layer 23 is provided, and the vapor deposition step is performed while, using the distance measuring member 11 (distance measuring section) capable of measuring the distance M (first distance) to the substrate 21 supported by the can roller 7, at the position upstream of the nozzle 9a in a direction of the movement of the substrate 21, and the position adjusting member 13 (position adjusting section) capable of adjusting the distance L (second distance) between the nozzle 9a and the surface of the substrate 21 by changing the position of the vapor deposition source 9 relative to the substrate 21, and based on a result of measurement of the distance M by the distance measuring member 11, control is performed by the position adjusting member 13 so that the distance L is constant.

Consequently, even if the position of the surface of the substrate 21 that moves in such a manner that the substrate 21 is supported by the can roller 7 varies, the distance M (or the distance variation dM) is measured at the position upstream of the nozzle 9a by the distance measuring member 11, and based on a result of the measurement, at a timing when the measurement area of the substrate 21 reaches the vapor deposition area, the position of the vapor deposition source 9 is changed by the position adjusting member 13, whereby an adjustment can be made so that the vapor deposition source-substrate distance L is constant. Accordingly, while the vapor deposition source-substrate distance L is maintained constant, vapor deposition can be performed. Accordingly, a variation in thickness of an organic layer can be suppressed, enabling provision of a high-quality organic EL device with suppression of emission color variation. Furthermore, manufacture of low-quality organic EL devices can be prevented, enabling enhancement in yield and thus enabling reduction in cost.

Also, as a variation in thickness of an organic layer is smaller, an emission color variation in an organic EL device can be suppressed more, and when the variation in thickness is made to be, for example, within ±2%, the emission color variation is more reliably suppressed, enabling provision of a higher-quality organic EL device.

Although the organic EL device manufacturing method and apparatus according to the present invention are ones such as described above, the present invention is not limited to the respective embodiments and a change of design can arbitrarily be made within the scope intended by the present invention. For example, although in the above-described embodiment, the distance measuring members 11 are provided at the respective vapor deposition sources 9, otherwise, fixing members can be separately provided at respective positions upstream of the vapor deposition area in the direction of the rotation of the can roller 7 in the vacuum chamber 3, and the respective distance measuring members 11 can be provided at the fixing members to use the distance measuring members 11.

Also, although in the above-described embodiment, the position adjusting members 13 are fixed to the inner wall 3a of the vacuum chamber 3 via the fixing members 15, otherwise, for example, the position adjusting members 13 can directly be fixed to the inner wall 3a. Furthermore, although in the above-described embodiment, the organic layer forming material 22 is evaporated in each vapor deposition source 9, it is possible to introduce an organic layer forming material 22 evaporated by a separate device into each vapor deposition source 9 and discharge the organic layer forming material 22 from a nozzle of the vapor deposition source 9.

Also, although in the above-described embodiment, the substrate supply device 5 is arranged in the vacuum chamber 3, a method for supplying the substrate 21 to the can roller 7 is not specifically limited as long as the substrate 21 can be fed out to the can roller 7. Furthermore, although in the above-described embodiment, the substrate 21 for which the vapor deposition step has finished is wound up, it is possible to subject the substrate 21 to a step such as cutting without being wound up.

### Example

Next, the present invention will be described in further detail taking an example; however, the present invention is not limited to such example.

One vapor deposition source 9 was arranged in the above-described manufacturing apparatus 1 according to the first embodiment, and using tris(8-hydroxyquinoline)aluminum (Alq3) as a material for forming a light-emitting layer 25a and using PET with a total length of 100 m as a substrate 21, an IZO layer is formed over the substrate 21 in advance as an anode layer 23 and then the substrate 21 with the IZO layer thereon was wound up.

Also, a piezoelectric actuator (PFT, which is a metal-sealed stacked piezoelectric actuator manufactured by Nihon Ceratec Co., Ltd.) was used as the position adjusting member 13, and a displacement sensor (HL-G1, which is a laser displacement sensor manufactured by Panasonic Electric Works Co., Ltd.) was used as the distance measuring member 11. By the organic EL device manufacturing method according to the first embodiment, while a position of the vapor deposition source 9 is adjusted, Alq3 is evaporated in the vapor deposition source 9 and the evaporated Alq3 is vapor-deposited on the IZO layer formed over the substrate 21, whereby a light-emitting layer 25a is successively formed.

A thickness of the formed light-emitting layer 25a was measured in such a manner that a center in a width direction of the substrate 21 was measured at intervals of 1 m in a longitudinal direction using Dektak, which is a stylus surface profiler manufactured by ULVAC, and a thickness accuracy in the longitudinal direction was calculated by thickness accuracy=(maximum value-minimum value of thickness)/2/(average thickness)×100(%). As a result, the thickness accuracy in the longitudinal direction was ±2%.

### Comparative Example

In a manner similar to that of the example except a vapor deposition source 9 being directly fixed to a fixing member 15 without interposition of a position adjusting member 13 and the arrangement of the vapor deposition source 9 being fixed without provision of a distance measuring member 11, Alq3 was vapor-deposited on an IZO layer formed over a substrate 21 including PET to form a light-emitting layer 25a, and a thickness accuracy in a longitudinal direction was calculated. As a result, the thickness accuracy in the longitudinal direction was ±10%.

The above result shows that an organic EL device manufacturing method and apparatus according to the present invention enables suppression of variation in thickness of an organic layer formed over an anode layer 23 on a substrate 21, and thus enabling suppression of emission color variation in an organic EL device.

### REFERENCE SIGNS LIST

1: organic EL device manufacturing apparatus, 3: vacuum chamber, 3a inner wall, 5: substrate supply device (substrate supply section), 7: can roller, 9 vapor deposition source, 9a: nozzle, 11: distance adjusting member (distance measuring section), 13: position adjusting member (position adjusting section), 21: substrate, 23: anode layer (electrode layer), 25a: light-emitting layer (organic layer)

1-5. (canceled)

6. An organic EL device manufacturing method in which while a strip-shaped substrate with an electrode layer formed thereover is moved, an organic layer is formed over a side of the substrate on which the electrode layer is provided, the method comprising
a vapor deposition step of supplying the substrate, and while moving the substrate with a side thereof, on which the electrode layer is not provided, in contact with a surface of a can roller that rotates, discharging an evaporated organic layer forming material from a nozzle of a vapor deposition source arranged so as to face the can roller, to form an organic layer over the side of the substrate on which the electrode layer is provided,
wherein the vapor deposition step is performed while,
using a distance measuring section capable of measuring a first distance to the substrate supported by the can roller, at a position upstream of the nozzle in a direction of the movement of the substrate, and
a position adjusting section capable of adjusting a second distance between the nozzle of the vapor deposition source and a surface of the substrate, and
based on a result of measurement of the first distance by the distance measuring section, control is performed by the position adjusting section so that the second distance is constant.

7. The organic EL device manufacturing method according to claim 6, wherein the position adjusting section changes a position of the vapor deposition source by a change in shape of a piezoelectric actuator.

8. The organic EL device manufacturing method according to claim 6, wherein the distance measuring section is provided at the vapor deposition source.

9. The organic EL device manufacturing method according to claim 6, wherein the distance between the nozzle and the surface of the substrate is not more than 15 mm.

10. A method for manufacturing an organic EL device comprising the steps of:
supplying a strip-shaped substrate having a first surface over which an electrode layer is formed and a second surface over which an electrode layer is not formed, so that the second surface is in contact with a surface of a can roller that rotates; and
forming an organic layer over the first surface by discharging an evaporated organic layer forming material from a nozzle of a vapor deposition source arranged so as to face the can roller, while measuring a first distance by a distance measuring section between the distance measuring section and the first surface of the strip-shaped substrate supported by the can roller at a position upstream of the nozzle in a direction of moving the strip-shaped substrate, adjusting a second distance between the nozzle and the first surface of the strip-shaped substrate by using a position adjusting section, and controlling the second distance based on a result of measurement of the first distance.

11. The method according to claim 10, wherein the position adjusting section changes a position of the vapor deposition source by changing a shape of a piezoelectric actuator.

12. The method according to claim 10, wherein the distance measuring section is provided at the vapor deposition source.

13. The method according to claim 10, wherein the second distance between the nozzle and the first surface is not more than 15 mm.

14. An organic EL device manufacturing apparatus comprising:
a substrate supply section for supplying a strip-shaped substrate having a first surface over which an electrode layer is formed and a second surface over which an electrode layer is not formed;
a can roller that rotates along with movement of the strip-shaped substrate while being in contact with the second surface;
a vapor deposition source arranged so as to face the can roller, for discharging an evaporated organic layer forming material from a nozzle to form an organic layer over the first surface;
a distance measuring section for measuring a first distance between the distance measuring section and the first surface of the strip-shaped substrate supported by the can roller, at a position upstream of the nozzle in a direction of the movement of the strip-shaped substrate; and
a position adjusting section for adjusting a second distance between the nozzle and the first surface based on a result of measurement of the first distance.

15. The organic EL manufacturing apparatus according to claim 14, wherein the position adjusting section changes a position of the vapor deposition source by changing a shape of a piezoelectric actuator.

16. The organic EL manufacturing apparatus according to claim 14, wherein the distance measuring section is provided at the vapor deposition source.

17. The organic EL manufacturing apparatus according to claim 14, wherein the second distance between the nozzle and the first surface is not more than 15 mm.
